(19) United States
(12) Patent Application Publication
(10) Pub. No.: US 2006/0035446 A1
(43) Pub. Date: Feb. 16, 2006

(54) Apparatus of catalytic molecule beam epitaxy and process for growing III-nitride materials using the apparatus

(76) Inventors: Chun-Yen Chang, Hsinchu City (TW); Tsung-Hsin Chen, Taipei City (TW)

Correspondence Address: BUCKNAM AND ARCHER, 1077 Northern Boulevard, Roslyn, NY, 11576, US

(21) Appl. No.: 11/048,548

(22) Filed: Feb. 1, 2005

(30) Foreign Application Priority Data
Aug. 13, 2004 (TW) 093124378

(51) Int. Cl. H01L 21/20; H01L 21/36; H01L 31/20

(52) U.S. Cl. 438/483

(57) ABSTRACT

This invention relates to an apparatus of catalytic molecule beam epitaxy (cat-MBE) and process for growing Group III nitride materials using thereof, characteristically in that said apparatus is equipped with a hot wire to catalytically decompose gaseous ammonium or nitrogen molecule into activated nitrogen radicals as the nitrogen source for growing epitaxial layers by MBE.

### FIELD OF THE INVENTION

This invention relates to an epitaxy apparatus of III-nitride, particularly to an apparatus of catalytic molecule beam epitaxy (catalytic MBE), which is characterized in that, said apparatus is equipped with a hot wire to catalytically decompose gaseous ammonium or nitrogen molecule into activated nitrogen radicals as the nitrogen source for growing epitaxy by MBE.

### DESCRIPTION OF THE RELATED PRIOR ART

The most common technologies used for conventional growth of Group III-nitride materials are: metal-organic chemical vapor deposition (MOCVD) and molecule beam epitaxy (MBE).

As to MOCVD technology, the growth rate is fast and the thickness is precisely controlled, so that it is particularly applicable to mass production of LEDs and LDs. Therefore, Emcore Company and Aixtron Company in U.S. and Tomas Swan Company in UK have developed MOCVD apparatuses used for mass production of gallium nitride. However, there are some obvious drawbacks in terms of MOCVD technology including higher growth temperature, higher pressure, and consumption of a large amount of ammonia to maintain the chemical composition of gallium nitride film. Besides, due to higher Reynolds number of ammonia, it is easy for fluid to produce turbulence phenomenon, so that the design of growth reactor and the control on growth uniformity of film are of technical difficulty, and it is not easy to install in-situ analysis elements into the system.

In contrast to the above MOCVD, to grow gallium nitride with MBE technology is capable to conduct at low temperature and low pressure with high growth uniformity of film and slow growth rate, so that it is possible to control the film thickness more preciously to atomic layer order, and is particularly applicable to material growth technology for production of quantum well layer structure. As molecule beams of each source in MBE technology are transmitted to substrate independently, it is possible to eliminate the homogeneous reaction between the sources in reactor space before they are transmitted to substrate. In addition, due to high vacuum degree in MBE system, normally at 10⁻¹⁰ torr, the background contamination of film materials originated from contaminants such as carbon and oxygen is low.

However, the drawback of MBE technology is, since the feature of NH₃ and N₂ is difficult to be decomposed at low temperature, currently MBE epitaxy of gallium nitride can only be enhanced by radio frequency (RF) and electron cyclotron resonance (ECR) plasmas to excite NH₃ and N₂ as nitrogen source. For example, when metal gallium or metal-organic gallium is used as gallium source, it is possible to react on the substrate surface to form gallium nitride; however, it is easy for high energy ion stream generated from RF or ECR plasma to damage film, so that the quality of gallium nitride epitaxial layer is obviously reduced.

For example, U.S. Pat. No. 6,146,458 discloses a molecule beam epitaxy, to improve present MBE technology, which comprises introducing NH₃ gas via first conduit and Group III gas via second conduit, in which NH₃ gas is introduced by RF as conventional MBE; in addition, U.S. Pat. No. 6,500,258 discloses a growth process for semiconductor crystal layer by MBE technology, which is characterized in that, mainly for production of Group III nitride semiconductor layer, to control temperature of substrate by using time difference, and to introduce NH₃ gas at right time to elevate V/III ratio. However, NH₃ gas is still introduced by RF as conventional MBE technology, so that it is possible for high-energy ion stream to damage film as U.S. Pat. No. 6,146,458. Further, U.S. Pat. No. 5,637,146 discloses a growth process and apparatus for Group III nitride semiconductor layer, which is characterized in that, nitrogen is supplied through RF plasma-excited radical atom technology, but there are still problems regarding epitaxial layer damage present. In the present invention, nitrogen source is supplied through hot wire catalytic decomposition of NH₃, so that obviously there are no problems regarding film damage by high-energy ion stream present as in conventional high-energy dissociation of nitrogen source by RF or ECR plasmas.

### SUMMARY OF THE INVENTION

The main object of the invention is to provide a catalytic molecule beam epitaxy (catalytic MBE) process and apparatus for growth of Group III nitride materials, which solves the problems of high energy ion stream damage in conventional molecule beam epitaxy due to RF or ECR, by supplying a stable activated nitrogen source, so that the quality of GaN epitaxial layer is elevated while maintaining a growth rate comparable to RF or ECR molecule beam epitaxy.

### BRIEF DESCRIPTION OF THE DRAWINGS

FIG. 1 is a scheme showing a catalytic molecule beam epitaxy (cat-MBE) apparatus in a preferred embodiment of the present invention;

FIG. 2 is a TEM image showing the cross-sectional GaN sample grown by a cat-MBE apparatus according to the present invention; and

FIG. 3 is the x-ray diffraction curve of GaN sample grown by a cat-MBE apparatus according to the present invention.

### DETAILED DESCRIPTION OF THE INVENTION

The catalytic molecule beam epitaxy apparatus of the present invention includes: 1) a cool-wall stainless steel super ultra-high vacuum system used as environment for growing Group III nitride materials; 2) a hot wire used for catalytically decomposing gases comprising nitrogen; 3) a solid Group III metal source used for providing Group III elements needed in the growth of Group III nitride semiconductor, such as Ga, Al or In, wherein, when ammonia or nitrogen are passed through hot wire, they are catalytically decomposed to produce activated ions comprising nitrogen, and said activated ions and Group III elements arrive at substrate in the form of molecule beam, react thereon to form Group III nitride epitaxial layer.

In the preferred embodiments of the present invention, said ammonia can be replaced by other gases of compounds comprising nitrogen, such as N₂, NₓCl_{y} etc.; the N activated ions produced when ammonia is passed through hot wire may be N* or NH* ion or other activated N component ions. The solid Group III source in the invention comprises high purity metals like Ga, Al and In.

The molecule beam epitaxy apparatus of the present invention includes a hot wire, a main reactor, a loading chamber, a heater, an entrance and exit for wafer loading in and out, shutters, a molecule source crucible set, and a pump system for maintaining vacuum. It is characterized in that a stable and activated catalytic hot wire is provided to produce activated ions comprising nitrogen such as N* or NH* ion or other activated N component ions, when, for example, ammonia, are passed therethrough. The materials of the hot wire comprise high melting-point metals like tungsten (W), tantalum (Ta), molybdenum (Mo), rhenium (Re), niobium, (Nb), platinum (Pt), titanium (Ti) etc., with tungsten (W) being the most preferred. The temperature of the hot wire depends on needed nitrogen sources and materials, and the range is between 1000° C.˜2500° C., with 1200° C.˜1700° C. being the most preferred.

### EMBODIMENT

In order to clearly demonstrate the above and other objects, features and advantages of the present invention, a preferred embodiment is presented in connection with accompanied figures for the explanation thereof, however, the content and scope of the present invention is not limited thereto.

FIG. 1 is a scheme showing a preferred embodiment of the present invention. Main reactor 20 of catalytic molecule beam epitaxy (catalytic MBE) apparatus 120 is made of stainless steel, and the wall is water-cooled. The heater 40 is capable to heat up to 1200° C., rotate, and carry 1˜2-inch wafers. Molecule source crucible set provides Group III elements like Ga, Al, etc., and solid Mg and Si sources for use as P and N types dopant sources. Nitrogen source is consisted of activated N or NH ions, which are produced by catalytic decomposition of high purity NH₃ gas by passing through hot wire 10. This is the core of the present invention. The vacuum states of main reactor 20 and loading chamber 30 are maintained by a 1300 l/s and a 600 l/s molecular pump respectively, and the highest vacuum can be reached up to 3×10⁻⁹ torr and 5×10⁻⁶ torr respectively. There is a reflective high-energy electron diffraction (RHEED) analyzer 50 installed in main reactor 20, in order to conduct an in-situ observation on film growth surface in this preferred embodiment. Entrance and exit for chip web 60 is used for loading and removing of wafers.

The general steps for growing GaN epitaxial film by using the present apparatus are:

(1) Firstly, a 1-inch sapphire (0001) substrate is cleaned with acetone and methanol, etched by a mixed solution formulated with H₂SO₄:H₃PO₄ of 1:3, and rinsed with DI water and dried with N₂;

(2) After clean pretreatment, the substrate is immediately loaded into loading chamber 30, and passed to main reactor 20 when the vacuum degree in loading chamber 30<2×10⁻⁶ torr; the temperature of main reactor is lowered to 500° C. for nitridation treatment for 5 minutes after the substrate is annealed at 900° C. for 10 minutes, and a low-temperature GaN epitaxial buffer layer of thickness of 25 nm is grown at 500° C., finally a GaN epitaxial layer of thickness of 3.5 μm is grown after elevating the temperature to 760° C. In which, NH₃ gas flow rate is controlled at 50 sccm, wire temperature is 1500° C., temperature of Ga source is controlled at 980° C., and growth pressure is 10⁻⁴ torr during the growth process.

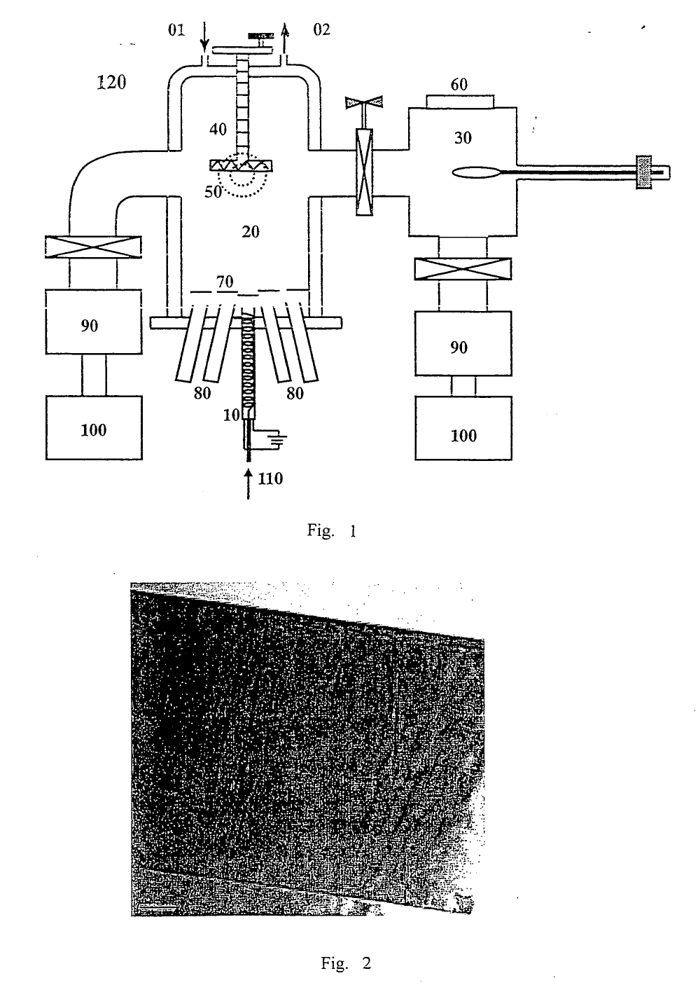

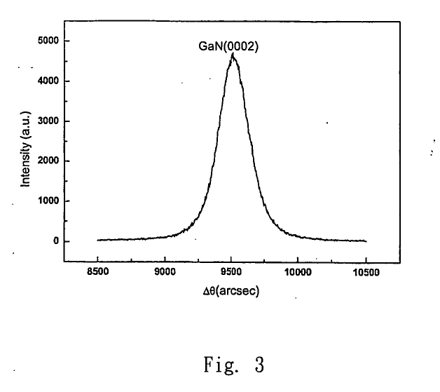

FIG. 2 is a TEM image showing the cross-sectional GaN sample grown by cat-MBE apparatus 120 according to the present invention; and FIG. 3 is the x-ray diffraction curve of GaN sample grown by cat-MBE apparatus 120 according to the present invention. The above results show the crystal quality of GaN samples grown by cat-MBE apparatus 120 used in the preferred embodiment is very good.

### DESIGNATION OF MAIN COMPONENTS

01 Inlet of cooling water
02 Outlet of cooling water
10 Hot wire
20 Main reactor
30 Loading chamber
40 Heater
50 Reflective high-energy electron diffraction analyzer (RHEED)
60 Entrance and exit for chip wafers
70 Shutter
80 Molecule source crucible set
90 Turbo pump
100 Mechanical pump
110 High purity ammonia
120 Catalytic molecule beam epitaxy apparutus

We claim:

1. A process for growing Group III nitride materials by using catalytic molecule beam epitaxy, which grows Group III nitride epitaxial layer in molecule beam epitaxy apparatus and comprises:
(1) providing a substrate;
(2) providing a solid metal to supply Group III metal elements; and
(3) providing a hot wire to catalytically decompose gases comprising nitrogen, wherein, when gases comprising nitrogen are passed through hot wire, said gases comprising nitrogen are catalytically decomposed by the hot wire to produce activated ions, and said activated ions react with Group III elements to form Group III nitride epitaxial layer on the heated substrate.

2. Process according to claim 1, wherein the gases comprising nitrogen are amonnia, nitrogen or NₓCl_{y}.

3. Process according to claim 1, wherein the activated ions are N* ion, NH* ion or NH₂* ion.

4. Process according to claim 1, wherein the Group III metal includes Ga, Al or In.

5. A catalytic molecule beam epitaxy apparatus for use in process as described in claim 1, which comprises:
(1) a cool-wall stainless steel ultra-high vacuum system used as environment for growing Group III nitride materials;
(2) a hot wire used for catalytically decompose gases comprising nitrogen; and
(3) a solid Group III metal source used for providing Group III elements needed in the growth of Group III nitride semiconductor,
wherein, when ammonia or nitrogen are passed through hot wire, they are catalytically decomposed to produce activated ions comprising nitrogen, and said activated ions and Group III elements arrive at the heated substrate in the form of molecule beam, react thereon to form Group III nitride epitaxial layer.

6. Catalytic molecule beam epitaxy apparatus as described in claim 5, wherein the activated ions are N* ion, NH* ion or NH₂* ion.

7. Catalytic molecule beam epitaxy apparatus as described in claim 5, wherein the catalytic hot wire comprises high melting-point metals like tungsten (W), tantalum (Ta), molybdenum (Mo), rhenium (Re), niobium (Nb), platinum (Pt), and titanium (Ti).

8. Catalytic molecule beam epitaxy apparatus as described in claim 5, wherein Group III elements is supplied by a solid metal.

9. Catalytic molecule beam epitaxy apparatus as described in claim 8, wherein the solid metal includes Ga, Al or In.
